(19) United States
(12) Patent Application Publication
(10) Pub. No.: US 2019/0309418 A1
(43) Pub. Date: Oct. 10, 2019

(54) MULTIZONE ROTATABLE DIFFUSER APPARATUS

(71) Applicant: Applied Materials, Inc., Santa Clara, CA (US)

(72) Inventors: Akshay GUNAJI, Bengaluru (IN); Karthik JANAKIRAMAN, San Jose, CA (US); Madhukar Chandrakant GULEDGUDD, Bengaluru (IN); Akshay DHANAKSHIRUR, Hubli-Dharwad City (IN)

(21) Appl. No.: 16/369,974

(22) Filed: Mar. 29, 2019

(30) Foreign Application Priority Data
Apr. 6, 2018 (IN) 201841013169

(51) Int. Cl. C23C 16/455

(52) U.S. Cl. CPC C23C 16/45559; C23C 16/45589

(57) ABSTRACT

The present disclosure relates to a rotatable diffuser apparatus for use in semiconductor process chambers. The apparatus includes a diffuser plate having holes disposed in regions across the plate. A shaft disposed through a dynamic fluid seal allows the plate to be rotated while maintaining desired pressures inside the chamber. The plate may be rotated to align holes in the regions with holes disposed in a fixed blocker plate. By varying the amount of holes aligned or the degree of alignment in different regions of the diffuser, the radial distribution of process gases may be adjusted.

### CROSS-REFERENCE TO RELATED APPLICATIONS

This application claims benefit of Indian Provisional Patent Application 201841013169 filed on Apr. 6, 2018 at the Indian Patent Office, which is herein incorporated by reference.

### BACKGROUND

### Field

The present disclosure generally relates to a rotatable diffuser apparatus for use in semiconductor process chambers.

### Description of the Related Art

In the fabrication of integrated circuits, deposition processes, such as chemical vapor deposition (CVD), are used to deposit films of various materials on substrates. In plasma-enhanced chemical vapor deposition (PECVD), for instance, electromagnetic energy is applied to at least one precursor gas or vapor to generate a plasma.

Uniformity of deposited films can vary from process to process, depending on the type of film deposited, the precursors used to form the film, and the process parameters employed during film deposition. For instance, radial film thickness non-uniformity occurs when a film thickness at a center of the substrate is less than or greater than a film thickness near the edge of the substrate. Conventional process chambers utilize different diffuser systems or apparatus for each process to achieve a uniform deposition profile to improve radial thickness uniformity. However, utilization of different systems and apparatus to modulate film deposition characteristics is time consuming and increases substrate transfer operations between multiple chambers which reduces throughput. Moreover, conventional systems often lack the ability to modulate characteristic of process chamber components in-situ to influence film deposition characteristics.

Accordingly, what is needed in the art are improved apparatus for film deposition processes.

### SUMMARY

In one embodiment, a rotatable diffuser apparatus is provided. The rotatable diffuser apparatus includes a plate having a first region defined by a first radius with a first plurality of holes disposed therein. The plate has an annular second region extending from the first radius to a second radius with a second plurality of holes disposed therein. The plate has an annular third region extending from the second radius to an edge of the plate with a third plurality of holes disposed therein. A shaft has an end disposed adjacent to the first region of the plate. A plurality of support struts extend from the shaft and are coupled to the plate. A dynamic fluid seal is disposed around the shaft.

In another embodiment, a lid assembly for a process chamber is provided. The lid assembly includes a first plate with a plurality of holes formed therethrough. A lid is coupled to the first plate, defining a volume between a surface of the lid and a surface of the first plate. A second plate is disposed in the volume between the first plate and the lid. The second plate has a first region defined by a first radius with a second plurality of holes disposed therein. The second plate has an annular second region extending from the first radius to a second radius with a third plurality of holes disposed therein. The second plate has an annular third region extending from the second radius to an edge of the second plate with a fourth plurality of holes disposed therein. A shaft extends through the lid and has an end disposed adjacent to the first region of the second plate. A plurality of support struts extend from the shaft and are coupled to the second plate. A dynamic fluid seal is disposed around the shaft.

In another embodiment, a process chamber is provided. The process chamber includes a chamber body defining a process volume. A substrate support is disposed in the process volume. A faceplate is coupled to the chamber body opposite the substrate support. A first plate is coupled to the faceplate. The first plate has a plurality of holes formed therethrough. A lid is coupled to the first plate, defining a volume between a surface of the lid and a surface of the first plate. A second plate is disposed in the volume between the first plate and the lid. The second plate has a first region defined by a first radius with a second plurality of holes disposed therein. The second plate has an annular second region extending from the first radius to a second radius with a third plurality of holes disposed therein. The second plate has an annular third region extending from the second radius to an edge of the second plate with a fourth plurality of holes disposed therein. A shaft extends through the lid and has an end disposed adjacent to the first region of the second plate. A plurality of support struts extend from the shaft and are coupled to the second plate. A dynamic fluid seal is disposed and around the shaft.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 illustrates a cross-sectional schematic view of a process chamber with a rotatable diffuser apparatus according to an embodiment described herein.

FIG. 2 illustrates a plan view of a diffuser plate with support struts and a shaft according to an embodiment described herein.

FIG. 3 illustrates a cross-sectional schematic view of a lid assembly with the rotatable diffuser apparatus of the process chamber of FIG. 1 according to an embodiment described herein.

FIG. 4A illustrates a plan view of a section of a surface of a blocker plate disposed adjacent to a diffuser plate according to an embodiment described herein.

FIG. 4B illustrates a plan view of a section of a surface of a blocker plate disposed adjacent to a diffuser plate according to an embodiment described herein.

FIG. 4C illustrates a plan view of a section of surface of a blocker plate disposed adjacent to a diffuser plate according to an embodiment described herein.

FIG. 5A illustrates a plan view of a quarter section of a diffuser plate with detailed cutaways illustrating holes according to an embodiment described herein.

FIG. 5B illustrates a plan view of a quarter section of a diffuser plate with detailed cutaways illustrating holes according to an embodiment described herein.

FIG. 5C illustrates a plan view of a quarter section of a diffuser plate with detailed cutaways illustrating holes according to an embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a rotatable diffuser apparatus for use in semiconductor process chambers. The apparatus includes a diffuser plate having holes disposed in regions across the plate. A shaft disposed through a dynamic fluid seal allows the plate to be rotated while maintaining desired pressures inside the chamber. The plate may be rotated to align holes in the regions with holes disposed in a fixed blocker plate. By varying the amount of holes aligned or the degree of alignment in different regions of the diffuser, the radial distribution of process gases may be tuned.

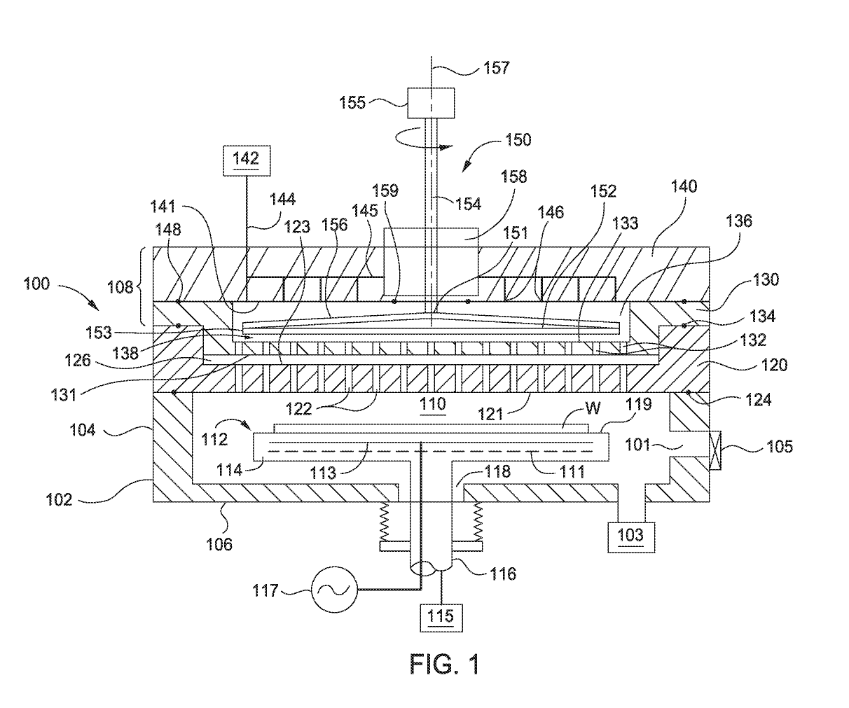

FIG. 1 illustrates a cross-sectional schematic view of a process chamber 100 according to one embodiment. A suitable, commercially available process chamber is the PRODUCER® PRECISION™ processing apparatus available from Applied Materials, Inc., Santa Clara, Calif. The process chamber 100 has a body 102 which includes a sidewall 104 and base 106. The chamber body 102 at least partially defines a process volume 110. The chamber body 102 is formed from a metallic material, such as aluminum or stainless steel. However, it is contemplated that other materials suitable for use with sub-atmospheric processing therein may be utilized.

A substrate support 112 is disposed within the process volume 110. The substrate support 112 is configured to support a substrate W thereon during processing within the process chamber 100. The substrate support 112 includes a support body 114 coupled to a shaft 116. The shaft 116 extends from the support body 114 through an opening 118 in the base 106 of the chamber body 102. The shaft 116 is coupled to an actuator 115 which engages the shaft 116 to vertically move the shaft 116, and the support body 114 coupled thereto, between a substrate loading position and a processing position. A vacuum system 103 is fluidly coupled to the process volume 110 to evacuate gases from the process volume 110. Although not illustrated, the vacuum system 103 is contemplated to include a pump which is configured to generate a sub-atmospheric pressure within the process volume 110.

During processing of the substrate W, the substrate W is disposed on an upper surface 119 of the support body 114, opposite of the shaft 116. A port 101 is formed in the sidewall 104 to facilitate ingress and egress of the substrate W into the process volume 110. A door 105, such as a slit valve or the like, is actuated to selectively allow the substrate W to pass through the port 101 to be loaded onto, or removed from, the substrate support 112. An electrode 113 is optionally disposed within the support body 114 and electrically coupled to a power source 117 through the shaft 116. The electrode 113 is selectively biased by the power source 117 to create an electromagnetic field to chuck the substrate W to the upper surface 119 of the support body 114 and/or to facilitate plasma generation or plasma biasing. In certain embodiments, a heater 111, such as a resistive heater, is disposed within the support body 114 to heat the substrate W disposed thereon.

A faceplate 120 is coupled to the chamber body 102 opposite the substrate support 112. More specifically, the faceplate 120 is coupled to the sidewall 104 of the chamber body 102. In one embodiment, the faceplate 120 is formed from a metallic material, such as an aluminum material or an aluminum alloy material. It is contemplated that the faceplate 120 may be fabricated from other suitable materials that are resistant to the process chemistry. For example, the faceplate 120 may be fabricated from a ceramic material. A seal 124, which may be an elastomeric material, such as an O-ring, is disposed between the sidewall 104 and the faceplate 120 where the faceplate 120 is coupled to the sidewall 104. The faceplate 120 has a plurality of holes 122 disposed therethrough. The plurality of holes 122 extend from a first surface 123 of the faceplate 120 to a second surface 121 of the faceplate 120. The second surface 121 of the faceplate 120 is disposed adjacent to the process volume 110 and the first surface 123 of the faceplate 120 is disposed adjacent to a volume 126. The volume 126 is at least partially defined by and positioned between the faceplate 120 and a blocker plate 130. The plurality of holes 122 enables fluid communication between the process volume 110 and the volume 126.

A lid assembly 108 is coupled to the faceplate 120. The lid assembly includes the blocker plate 130 which is coupled to the faceplate 120. A seal 134, which may be an elastomeric material, such as an O-ring, is disposed between the blocker plate 130 and the faceplate 120. The blocker plate 130 is formed from aluminum in one embodiment. However, it is contemplated that other suitable materials may be utilized. The blocker plate 130 has a first surface 131 disposed adjacent to the volume 126. A second surface 133 of the blocker plate 130 is disposed opposite the first surface 131. A plurality of holes 132 extend through the blocker plate 130 from the second surface 133 to the first surface 131. The plurality of holes 132 enable fluid communication between the volume 126 and a volume 136, which is disposed adjacent to the second surface 133 of the blocker plate 130.

The lid assembly 108 also includes a lid 140 disposed adjacent to the blocker plate 130. In one embodiment, the lid 140 is formed from a metallic material, such as an aluminum material or an aluminum alloy material. It is contemplated that other suitable materials may be utilized to fabricate the lid 140. The lid 140 is coupled to the blocker plate 130 and at least partially defines the volume 136 therein. A seal 148, which may be an elastomeric material, such as an O-ring, is disposed between the blocker plate 130 and the lid 140. The lid 140 has a surface 141 which is adjacent to the volume 136.

A plurality of gas channels 145 are formed in the lid 140. The gas channels 145 extend through the lid 140 to a plurality of ports 146 disposed in the surface 141. In one embodiment, the plurality of ports 146 is distributed along the surface 141 in a linear pattern. In another embodiment, the plurality of ports 146 is distributed along the surface 141 in a radial pattern. It is contemplated that the distribution of the plurality of ports 146 may be utilized to influence the distribution of gases entering the volume 136. In operation, gases enter the volume 136 through the plurality of ports 146 and travel through the plurality of gas channels 145 from a gas source 142 which is in fluid communication with the plurality of gas channels 145 via a conduit 144. It is contemplated that a single conduit or multiple conduits may be utilized to deliver gases from the gas source 142 to the plurality of gas channels 145.

The lid assembly 108 further includes a rotatable diffuser apparatus 150. The rotatable diffuser apparatus 150 includes a diffuser plate 152, which is disposed in the volume 136 between surface 141 of the lid 140 and second surface 133 of the blocker plate 130. The diffuser plate 152 is separated from the blocker plate 130 by a distance 138, which may be from about 100 microns to about 2 millimeters, for example about 1 millimeter. The diffuser plate 152 is coupled to a shaft 154 by support struts 156, which extend from the shaft 154 to the diffuser plate 152. In some embodiments, the support struts 156 extend from an end 151 of the shaft 154 to an edge 153 of the diffuser plate 152. The size, shape, and material of the support struts 156 are selected to minimize material deposition on surfaces of the support struts 156 during processing.

The shaft 154 extends through the lid 140. In one embodiment, the shaft 154 extends through a center region of the lid 140. A dynamic fluid seal 158 is disposed inside the lid 140 around the shaft 154. The dynamic fluid seal 158 may be a vacuum seal or a magnetic seal. A motor 155 is coupled to the shaft 154 to rotate the shaft 154 about an axis 157. The dynamic fluid seal 158 enables the shaft 154, which is driven by the motor 155, and the diffuser plate 152, coupled to the shaft 154 via the support struts 156, to rotate about the axis 157 while preventing fluid communication between the ambient atmosphere outside of the process volume 110 and the volumes 136, 126, 110 within the process chamber 100.

Advantageously, sealing provided by the dynamic fluid seal 158 is robust and suitable to withstand the temperatures and pressures present in the process chamber 100 during processing. The dynamic fluid seal 158 also provides a low-friction seal for the rotation of the shaft 154, thus reducing wear. In one embodiment, the dynamic fluid seal 158 is secured to the lid 140 by a seal 159, which may be an elastomeric material O-ring.

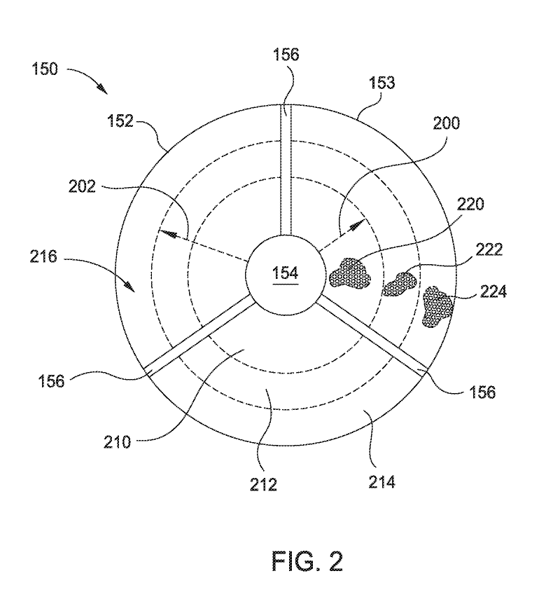

FIG. 2 illustrates a plan view of a portion of the rotatable diffuser apparatus 150. A cross section of the shaft 154 is shown, with support struts 156 extending from the shaft 154 to the edge 153 of the diffuser plate 152. The end 151 (not shown) of the shaft 154 is disposed adjacent to the center of the diffuser plate 152. Three support struts 156, which are spaced equally about the circumference of the diffuser plate 152, extend from the shaft 154 and are coupled to an upper surface 216 of the diffuser plate 152 adjacent the edge 153. In one embodiment, the support struts 156 are welded to the diffuser plate 152. In another embodiment, the support struts 156 are mechanically coupled to the diffuser plate 152, for example, by a threaded coupling, such as a screw or a bolt.

The diffuser plate 152 has a first region 210 in a center of the diffuser plate 152 which is defined by a first radius 200. An annular second region 212 extends from the first radius 200 to a second radius 202. An annular third region 214 extends from the second radius 202 to the edge 153.

Each of the regions 210, 212, and 214 has a plurality of holes disposed therein. A first plurality of holes 220 is disposed in the first region 210; a second plurality of holes 222 is disposed in the second region 212; and a third plurality of holes 224 is disposed in the third region 214. While only a portion of each of the plurality of holes 220, 222, 224 are illustrated, it is contemplated that each of the pluralities of holes 220, 222, 224 occupy a substantial totality of each of the first region, 210, the second region 212, and the third region 214, respectively. While three regions 210, 212, and 214 are discussed herein, it is contemplated that the embodiments described herein can be extended to any number of regions of hole alignment.

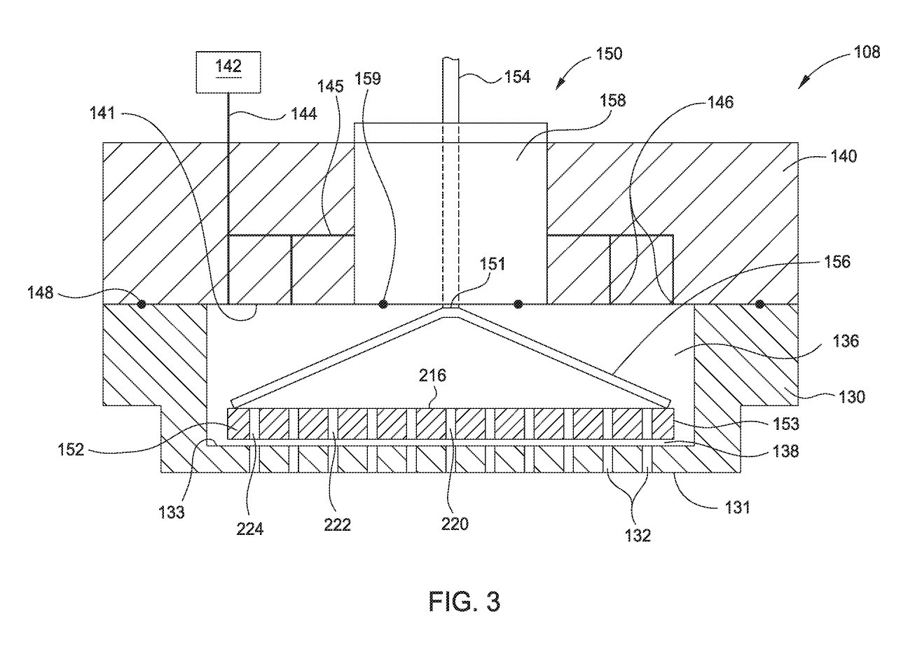

FIG. 3 illustrates a cross-sectional schematic view of the lid assembly 108, to show the rotatable diffuser apparatus 150 in further detail. In FIG. 3, the first plurality of holes 220, the second plurality of holes 222, and the third plurality of holes 224 in the diffuser plate 152 are shown. In the illustrated embodiment, each of the first plurality of holes 220, the second plurality of holes 222, and the third plurality of holes 224 are aligned adjacent to the holes 132 in the blocker plate 130. In this embodiment, a line of sight from the first surface 131 of the blocker plate 130 to the upper surface 216 of the diffuser plate 152 is substantially unoccluded. However, it is contemplated that one or more of the first plurality of holes 220, the second plurality of holes 222, and the third plurality of holes 224 may be at least partially misaligned with the holes 132 of the blocker plate 130. In this embodiment, a line of sight from the first surface 131 of the blocker plate 130 to the upper surface 216 of the diffuser plate 152 is at least partially occluded.

As described above, the holes 220, 222, and 224 are positioned such that rotations of the shaft 154 alter the alignment between the holes 220, 222, 224 of the diffuser plate 152 and the holes 132 in blocker plate 130. Hence, the number of holes aligned or the degree of alignment of the holes may be varied between regions 210, 212, and 214 (shown in FIG. 2) depending upon the rotational position of the diffuser plate 152 relative to the blocker plate 130.

In one embodiment, a first magnitude of rotation from a set zero point (e.g., substantial total alignment of the holes 220, 222, 224 and the holes 132) causes a greater number of the holes 220 in the first region 210 to be aligned, while fewer of the holes 222 and 224 in the second region 212 and the third region 214, respectively, are aligned. In another embodiment, a second magnitude of rotation from the set zero point causes a greater number of the holes 222 in the second region 212 to be aligned, while fewer of the holes 220 and 224 in the first region 210 and the third region 214, respectively, are aligned. In another embodiment, a third magnitude of rotation from a set zero point causes a greater number of the holes 224 in the third region 214 to be aligned, while fewer of the holes 220 and 222 in the first region 210 and second region 212, respectively, are aligned.

In this way, the deposition profile and radial uniformity of a deposition process may be dynamically modulated. Thus, use of the rotatable diffuser apparatus 150 enables additional methods of tuning characteristics for modulating film thickness. The rotatable diffuser apparatus 150 also reduces the use of separate diffuser plates for different processes, since the deposition profile can be altered between processes by rotating the diffuser plate 152.

It is contemplated that the rotational alignment characteristics of the diffuser plate 152 may be determined by the location and the size of the holes 220, 222, and 224 relative to the location and size of the holes 132. In one example, the holes 220, 222, and 224 have a diameter greater than a diameter of the holes 132. In another example, the holes 220, 222, 224 have a diameter less than the diameter of the holes 132.

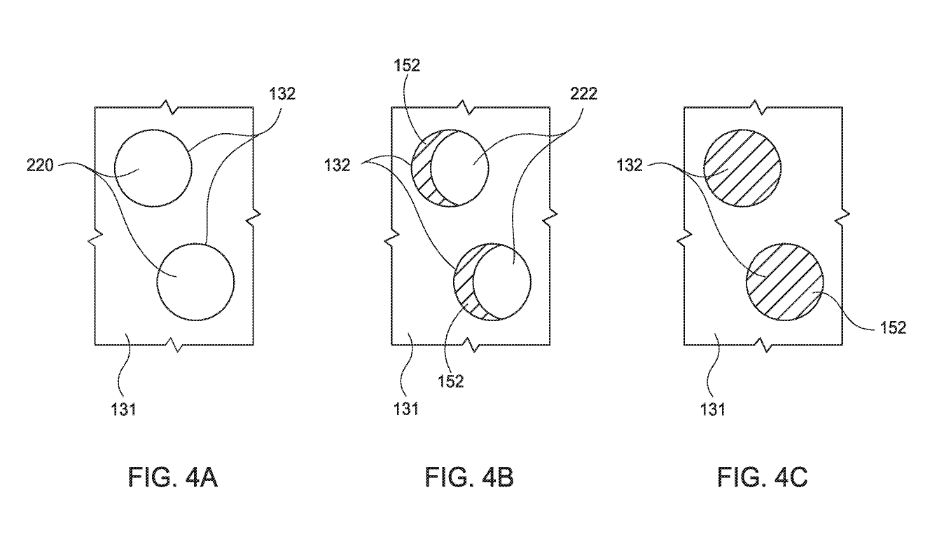

FIGS. 4A-4C illustrate plan views of sections of the surface 131 of the blocker plate 130, showing how the deposition profile may be altered. FIGS. 4A-4C illustrate views of three portions of the surface 131 of the blocker plate 130. FIG. 4A illustrates a portion adjacent to the first region 210 of the diffuser plate 152 (shown in FIG. 2). FIG. 4B illustrates a portion adjacent to the second region 212 of the diffuser plate 152 (shown in FIG. 2). FIG. 4C illustrates a portion adjacent to the third region 214 of the diffuser plate 152 (shown in FIG. 2).

As illustrated in FIG. 4A, the holes 220 in the first region 210 (as illustrated in FIG. 2) are aligned with the holes 132 of the blocker plate 130 so that the holes 132 are substantially unoccluded. As illustrated in FIG. 4B, the holes 222 in the second region 212 (as illustrated in FIG. 2) are aligned such that the holes 132 are partially occluded, such that the diffuser apparatus 152 is partially visible through the holes 132. As illustrated in FIG. 4C, the holes 224 in the third region 214 (as illustrated in FIG. 2) are aligned such that holes 132 are substantially occluded by the diffuser apparatus 152. It is contemplated that for each embodiment described above, the degree of occlusion may be selected along a continuum from total occlusion to substantially no occlusion.

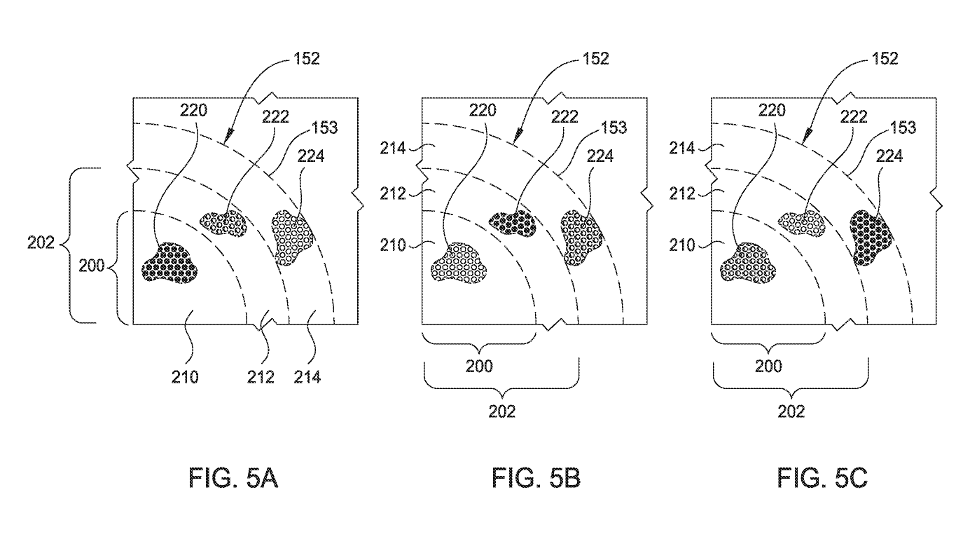

FIGS. 5A-5C illustrate plan views of quarter sections of the diffuser plate 152 with detailed cutaways illustrating holes 220, 222, and 224. Each of FIGS. 5A-5C illustrates a plan view of a quarter section of the diffuser plate 152, with the shaft 154 and support struts 156 (illustrated in FIG. 2) omitted for clarity. In each of FIGS. 5A-5C, the first radius 200 and the second radius 202 and the edge 153 of the diffuser plate 152 define the first region 210, the second region 212, and the third region 214, respectively. FIG. 5A illustrates an arrangement where more of the holes 220 in the first region 210 are aligned and fewer of the holes 222 and 224 are aligned in the second region 212 and the third region 214, respectively.

Analogously, FIG. 5B illustrates an arrangement where more of the holes 222 are aligned in the second region 212 and fewer of the holes 220 and 224 are aligned in the first region 210 and the third region 214, respectively. FIG. 5C illustrates an arrangement where more of the holes 224 are aligned in the third region 214 and fewer of the holes 220 and 222 are aligned in the first region 210 and the second region 212, respectively. Each of the aforementioned arrangements may be suited for a different deposition process, depending on the type of film to be deposited, the types of precursors utilized, and the desired degree of film thickness modulation. Hence, the diffuser apparatus 152 enables improved film thicknesses modulation and radial thickness uniformity for multiple processes, without the need to use a different diffuser for each process.

While the foregoing is directed to embodiments of the present disclosure, other and further embodiments of the disclosure may be devised without departing from the basic scope thereof, and the scope thereof is determined by the claims that follow.

What is claimed is:

1. A rotatable diffuser apparatus, comprising:
a plate, the plate comprising:
a first region defined by a first radius and having a first plurality of holes disposed therein;
an annular second region extending from the first radius to a second radius and having a second plurality of holes disposed therein; and
an annular third region extending from the second radius to an edge of the plate and having a third plurality of holes disposed therein;
a shaft having an end disposed adjacent to the first region of the plate;
a plurality of support struts extending from the end of the shaft and coupled to the edge of the plate; and
a fluid seal disposed around the shaft.

2. The rotatable diffuser apparatus of claim 1, further comprising:
a motor coupled to the shaft for rotating the shaft about an axis.

3. The rotatable diffuser apparatus of claim 1, wherein the plate is formed from aluminum.

4. The rotatable diffuser apparatus of claim 1, wherein the plurality of support struts comprise three support struts coupled adjacent a perimeter of the plate and spaced at equal angular distances from one another.

5. A lid assembly for a process chamber, comprising:
a first plate having a first plurality of holes formed therethrough;
a lid coupled to the first plate and at least partially defining a volume between a surface of the lid and a surface of the first plate;
a second plate disposed in the volume between the first plate and the lid, the second plate comprising:
a first region defined by a first radius and having a second plurality of holes disposed therein;
an annular second region extending from the first radius to a second radius and having a third plurality of holes disposed therein; and
an annular third region extending from the second radius to an edge of the second plate and having a fourth plurality of holes disposed therein;
a shaft extending through the lid and having an end disposed adjacent to the first region of the second plate;
a plurality of support struts extending from the end of the shaft and coupled to the edge of the second plate; and
a fluid seal disposed around the shaft.

6. The lid assembly of claim 5, further comprising:
a motor coupled to the shaft for rotating the shaft about an axis.

7. The lid assembly of claim 5, wherein the first plate is formed from aluminum.

8. The lid assembly of claim 5, wherein the second plate is formed from aluminum.

9. The lid assembly of claim 5, further comprising:
a plurality of channels formed in the lid and extending to a plurality of ports disposed in the surface of the lid.

10. The lid assembly of claim 5, wherein a diameter of the holes of the second plurality of holes, the third plurality of holes, and the fourth plurality of holes is greater than a diameter of the holes of the first plurality of holes.

11. The lid assembly of claim 5, wherein the first plate and the second plate are positioned about 1 micrometer apart.

12. The lid assembly of claim 5, wherein the plurality of support struts comprise three support struts spaced equally about a circumference of the second plate.

13. A process chamber, comprising:
a chamber body defining a process volume;
a substrate support disposed in the process volume;
a faceplate coupled to the chamber body opposite the substrate support;
a first plate coupled to the faceplate, the first plate having a first plurality of holes formed therethrough;
a lid coupled to the first plate and at least partially defining a volume between a surface of the lid and a surface of the first plate;
a second plate disposed in the volume between the first plate and the lid, the second plate comprising:
a first region defined by a first radius and having a second plurality of holes disposed therein;
an annular second region extending from the first radius to a second radius and having a third plurality of holes disposed therein; and
an annular third region extending from the second radius to an edge of the second plate and having a fourth plurality of holes disposed therein;
a shaft extending through the lid and having an end disposed adjacent to the first region of the second plate;
a plurality of support struts extending from the end of the shaft and coupled to the edge of the second plate; and
a fluid seal disposed around the shaft.

14. The process chamber of claim 13, further comprising:
a motor coupled to the shaft for rotating the shaft about an axis.

15. The process chamber of claim 13, wherein the first plate is formed from aluminum.

16. The process chamber of claim 13, wherein the second plate is formed from aluminum.

17. The process chamber of claim 13, further comprising:
a plurality of channels formed in the lid and extending to a plurality of ports disposed in the surface of the lid.

18. The process chamber of claim 13, wherein a diameter of the holes of the second plurality of holes, the third plurality of holes, and the fourth plurality of holes is greater than a diameter of the holes of the first plurality of holes.

19. The process chamber of claim 13, wherein the first plate and the second plate are positioned about 1 micrometer apart.

20. The process chamber of claim 13, wherein the plurality of support struts comprise three support struts spaced equally about a circumference of the second plate.
